(19) United States
(12) Patent Application Publication
(10) Pub. No.: US 2026/0206337 A1
(43) Pub. Date: Jul. 16, 2026

(54) MOVABLE CURING SYSTEM FOR ASSEMBLING OPTICAL PACKAGES

(71) Applicant: ASMPT Singapore Pte. Ltd., Singapore (SG)

(72) Inventors: Hong YAN, Hong Kong (CN); Chun Ting TANG, Hong Kong (CN); Liancheng YANG, Hong Kong (CN); Chi Piu WONG, Hong Kong (CN); Yin Fun NG, Hong Kong (CN)

(21) Appl. No.: 19/015,994

(22) Filed: Jan. 10, 2025

(51) Int. Cl. H10F 39/00; H10F 39/12

(52) U.S. Cl. CPC H10F 39/024; H10F 39/12; H10F 39/8063

(57) ABSTRACT

For assembling an optical package with first and second optical components, the first optical component is placed onto a transporter, and the transporter conveys the first optical component to a location where an optical alignment head is situated. The first optical component is then aligned with respect to the second optical component using the optical alignment head. An adhesive is dispensed onto the first optical component and the second optical component is attached onto the adhesive dispensed on the first optical component to form the optical package. Thereafter, the optical package is conveyed away from the optical alignment head using the transporter while simultaneously curing the adhesive with ultraviolet light projected from an ultraviolet system mounted on and movable with the transporter.

### FIELD OF THE INVENTION

The invention relates to the assembly of an optical package, such as during the production of a camera module, that utilizes a curing system for solidifying a liquid adhesive that has been applied for securing separate components comprised in the optical package.

### BACKGROUND AND PRIOR ART

In the production of an optical package, accurate alignment of a focusing lens module relative to an image sensor that is included in the camera is critical. The lens module should be aligned with respect to the image sensor during an active alignment (“AA”) process. After alignment, the image sensor is fixedly attached relative to the lens module by bonding. More specifically, after the lens module has been correctly aligned with respect to the image sensor during the AA process, they are typically bonded to each other using an adhesive. Usually, the adhesive used is a glue in liquid form when dispensed, but is curable using ultraviolet (“UV”) light to solidify the glue after it has been dispensed onto a peripheral surface surrounding the image sensor, before the optical module is positioned onto the glue for bonding.

During curing, since the UV light exposure time and range directly affects the productivity or units-per-hour (“UPH”) of an AA apparatus, and therefore affects an optical package production yield, the UV curing system is an important part of the AA apparatus.

FIG. 1A are isometric views of a flexible printed circuit (“FPC”) device 100 and a non-FPC device 101 respectively that are conventionally used to form optical packages. The FPC device 100 includes an image sensor 102 and a flexible circuit 104, whereas the non-FPC device 101 has an image sensor 102 but does not have a flexible circuit 104. For such an FPC device 100, a collet pick position 106 is located on the flexible circuit 104 whereat the FPC device 100 may be picked up by a collet (not shown) using vacuum suction exerted at the collet pick position 106. As for the non-FPC device 101, the collet would have to pick up the non-FPC device 101 at collet pick positions 107 that are at the edges or periphery of the image sensor 102 since there is no flexible circuit 104 present. This edge or peripheral area of the image sensor 102 overlaps with an area where glue is to be dispensed. The main difference in the AA process is that in the event of a glue dispensing failure, the non-FPC device 101 requires solidification of the glue before the defective image sensor 102 is offloaded to avoid contamination of a vacuum nozzle of a pick head that has to contact the collet pick positions 107 to remove the image sensor 102. The FPC device 100 has no such limitation.

FIG. 1B is an isometric view of lens modules 108 that have been placed onto the FPC device 100 and non-FPC device 101 respectively after the lens modules 108 have been properly aligned with the image sensors 102. A layer of glue 110, in particular glue that is configured to be curable by ultraviolet (“UV”) light, has been dispensed along a periphery of the image sensor 102. The lens module 108 is placed onto the dispensed glue 110. Thereafter, the glue 110 should be cured by illuminating it with UV light.

FIG. 1C is an isometric view of UV light 114 curing the glue 110 used for bonding the lens modules 108. The UV light 114 is transmitted from four UV lamps 112 that are arranged adjacent to the respective four corners of an optical package that is assembled by bonding the lens module 108 to the image sensor 102. After curing of the bond between the lens module 108 and the image sensor 102, assembly of the optical package would be completed.

FIG. 2 is an isometric view of a conventional AA apparatus 115. Such a conventional AA apparatus 115 generally includes an AA head 116 where a lens module 108 is to be actively aligned with an image sensor 102, a UV system 118 for curing the glue 110, and a sensor unit transporter (“SUT”) 120 for transporting an optical package between a loading and/or unloading position where a pick head 124 is located and the AA head 116. The SUT 120 is linearly movable along a guide rail 122 between these locations A glue dispenser 126 for dispensing the glue 110 and a glue inspection module 128 are also located between the location of the pick head 124 and the location of the AA head 116, where the SUT 120 would also stop at for the purposes of glue dispensing and glue inspection respectively.

Currently, an AA process conducted by the said conventional AA apparatus 115 comprises a series of steps which may include: (i) loading an FPC device 100 (or non-FPC device 101, as the case may be) containing an image sensor 102 onto the SUT 120 with the pick head 124 and a lens module 108 onto the AA head 116, (ii) transporting the image sensor 102 to the location of the AA head 116 where AA is to be performed, (iii) conducting AA, (iv) moving the aligned image sensor 102 with the SUT 120 to the location of the glue dispenser 126 and dispensing glue onto a periphery of the image sensor 102, (v) inspecting the dispensed glue at the glue inspection module 128 to check for potential defects, (vi) returning the image sensor 102 to the location of the AA head 116, (vii) conducting UV curing of the dispensed glue with the UV system 118 at the location of the AA head 116, (viii) after curing is completed, transporting the assembled optical package away from the AA head 116, and (ix) offloading the assembled optical package from the AA apparatus 115 with the pick head 124.

During the entire process, the UV lamps 112 for projecting the UV light 114 and its adjacent mechanisms comprised in the UV system 118 are fixedly arranged at the location of the AA head 116 where AA is being conducted. As such, the AA apparatus 115 must wait for the UV curing process to be completed at the location of the AA head 116 before the assembled optical package can be transported to the pick head 124 for offloading. In cases where there is a failure in the dispensing of the glue 110 onto a non-FPC device 101, the SUT 120 further needs to return to the location of the AA head 116 for UV curing before moving back to the location of the pick head 124 for offloading the non-FPC device 101 to avoid contamination of the pick head 124.

Thus, the waiting time for UV curing adversely affects the UPH of the AA apparatus 115. Furthermore, since an adjustment mechanism in the UV system 118 for adjusting the UV lamps 114 is fixedly mounted at the location corresponding to the position of the AA head 116, the adjustment angles that are possible are significantly restricted due to space constraints. This limitation decreases the operational efficiency of the UV system 118.

In other words, since the design of a conventional UV system 118 has a large adjustable mounting system comprising UV lamps 112 that is fixed around the AA head 116, the UV curing process has to proceed sequentially throughout the entire AA process flow. This increases the waiting time for the curing process that can only be conducted at the location of the AA head 116, which in turn affects the overall UPH of the AA apparatus 115.

It would be beneficial to incorporate a UV system design in an AA apparatus which avoids at least some of the aforesaid shortcomings of the prior art.

### SUMMARY OF THE INVENTION

It is thus an object of the invention to seek to provide a UV system that is able to conduct the UV curing process away from the location of the AA head during an optical package assembly operation to improve a UPH of an AA apparatus.

According to a first aspect of the invention, there is provided a method for assembling an optical package including first and second optical components, the method comprising the steps of: placing the first optical component onto a transporter; conveying the first optical component with the transporter to a location where an optical alignment head is situated; aligning the first optical component with respect to the second optical component using the optical alignment head; dispensing an adhesive onto the first optical component and attaching the second optical component onto the adhesive dispensed on the first optical component to form the optical package; and thereafter conveying the optical package away from the optical alignment head using the transporter while simultaneously curing the adhesive with ultraviolet light projected from an ultraviolet system mounted on and movable with the transporter.

According to a second aspect of the invention, there is provided a method for assembling an optical package including first and second optical components, the method comprising the steps of: placing the first optical component onto a transporter; conveying the first optical component with the transporter to a location where an optical alignment head is situated; aligning the first optical component with respect to the second optical component using the optical alignment head; dispensing an adhesive onto the first optical component and inspecting the dispensed adhesive at an adhesive inspection module; if adhesive dispensing failure is detected by the adhesive inspection module, conveying the first optical component towards an offloading location while simultaneously curing the adhesive with ultraviolet light projected from an ultraviolet system mounted on and moveable with the transporter; and removing the first optical component from the transporter after curing the adhesive.

According to a third aspect of the invention, there is provided an apparatus for assembling an optical package including first and second optical components, the apparatus comprising: an optical alignment head for aligning the first optical component with respect to the second optical component; a transporter for conveying the first optical component to a location where the optical alignment head is situated; an adhesive dispenser for dispensing an adhesive onto the first optical component before attaching the second optical component onto the adhesive dispensed on the first optical component at the optical alignment head to form the optical package; and an ultraviolet system mounted on and movable with the transporter such that ultraviolet light is projectable onto the optical package to cure the adhesive simultaneously with conveying the optical package away from the optical alignment head with the transporter.

It would be convenient hereinafter to describe the invention in greater detail by reference to the accompanying drawings which illustrate specific preferred embodiments of the invention. The particularity of the drawings and the related description is not to be understood as superseding the generality of the broad identification of the invention as defined by the claims.

### BRIEF DESCRIPTION OF THE DRAWINGS

A specific example of an AA apparatus in accordance with the invention will now be described with reference to the accompanying drawings, in which:

FIG. 1A is an isometric view of an FPC device and non-FPC device respectively,

FIG. 1B is an isometric view of lens modules that have been placed onto the FPC device and non-FPC device respectively, and FIG. 1C is an isometric view of UV light curing a glue used for bonding the lens module;

FIG. 2 is an isometric view of a conventional AA apparatus;

FIG. 3 is an isometric view of an AA apparatus according to the preferred embodiment of the invention;

FIG. 4A is a side view of the AA apparatus of FIG. 3 conducting AA, FIG. 4B is a side view of the glue being dispensed onto an image sensor module, FIG. 4C is a side view of the image sensor module undergoing glue inspection, FIG. 4D is a side view of the lens module being bonded onto the image sensor, and FIG. 4E is a side view of a bonded package being positioned for offloading;

FIG. 5 is an isometric view of an SUT comprised in the AA apparatus of FIG. 3;

FIG. 6 is an exploded view of the SUT shown in FIG. 5 with its UV system removed;

FIG. 7 is an isometric view of the UV system mounted on the SUT;

FIG. 8 is a flowchart showing a typical AA process flow where no glue dispensing failure is encountered; and

FIG. 9 is a flowchart showing an AA process flow where a glue dispensing failure is encountered.

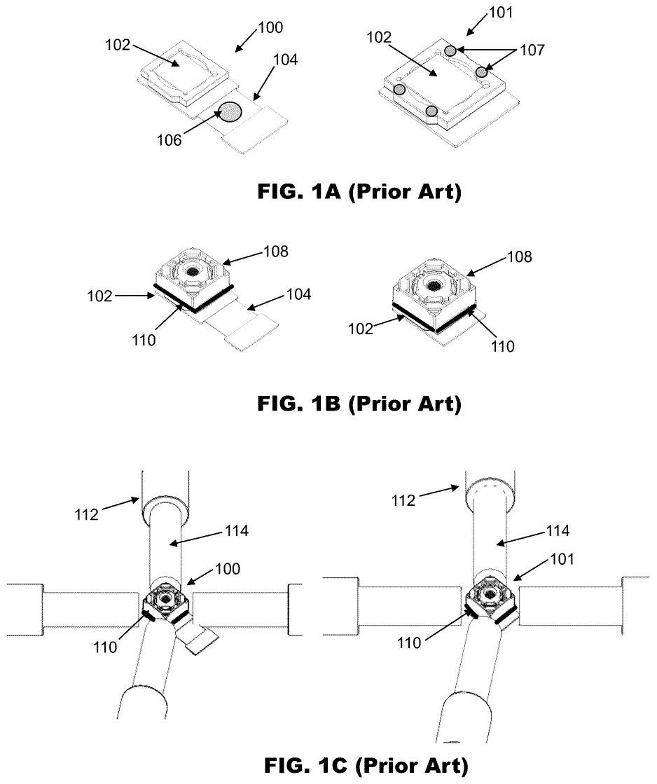

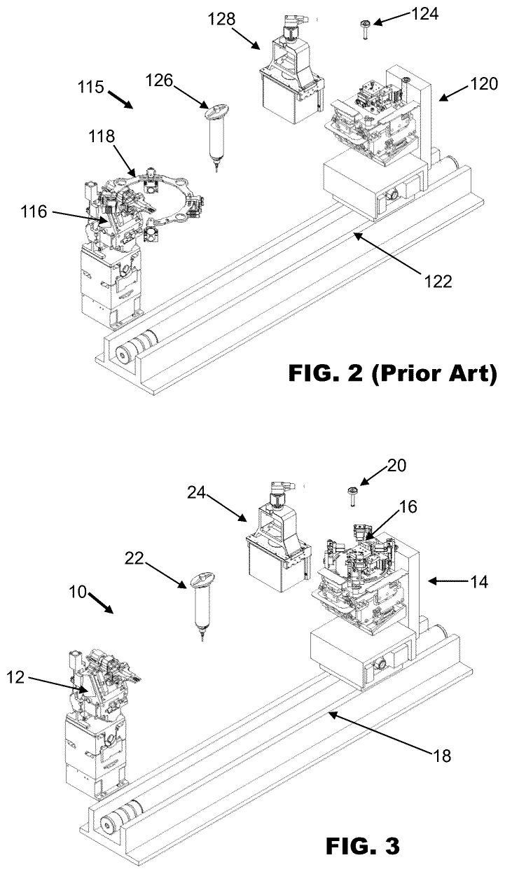

### DETAILED DESCRIPTION OF THE PREFERRED EMBODIMENTS OF THE INVENTION

FIG. 3 is an isometric view of an AA apparatus 10 according to the preferred embodiment of the invention for assembling an optical package. The AA apparatus 10 generally includes an optical alignment head or an AA head 12, where a first optical component such as an image sensor 102 may be actively aligned with respect to a second optical component such as a lens module 108, and the image sensor 102 and lens module 108 may be bonded to each other to form an optical package. Although the optical package typically comprises an image sensor 102 that is bonded to a lens module 108, different configurations are also possible, for instance one lens module 108 may be bonded to another lens module 108 to form the optical package. A transporter in the form of an SUT 120 is used for transporting an optical package between a loading and/or unloading position where a pick head 124 is located and the AA head 116.

In this preferred embodiment, a UV system 16 for curing the glue 110 is mounted onto, and is movable together with, the SUT 14. The SUT 14 is linearly movable along a guide rail 18 between the said locations. An adhesive dispenser for dispensing an adhesive, such as a glue dispenser 22 for dispensing glue 110, and a separate adhesive or glue inspection module 24 are also located between the location of the pick head 20 and the location of the AA head 12, where the SUT 14 would stop at for the purposes of glue dispensing and glue inspection respectively.

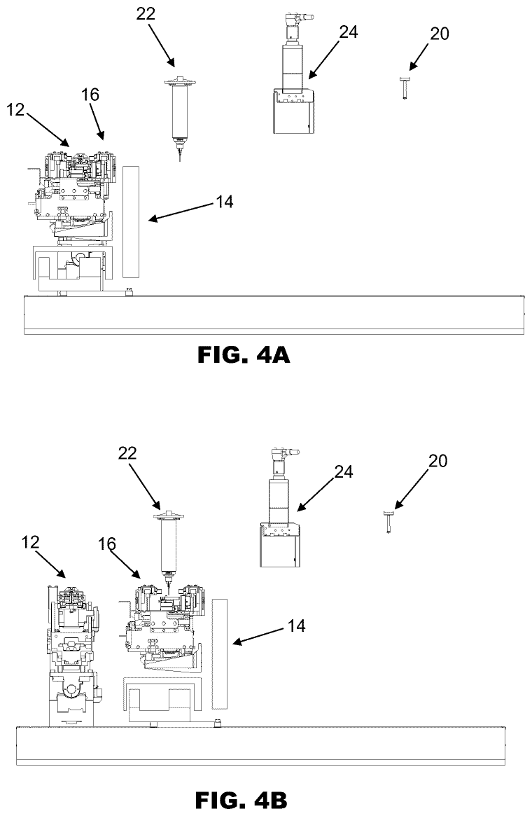

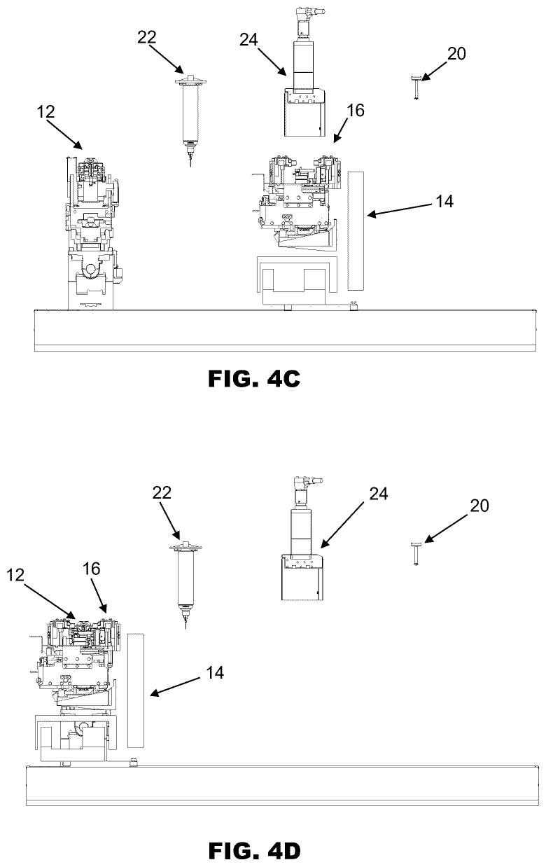

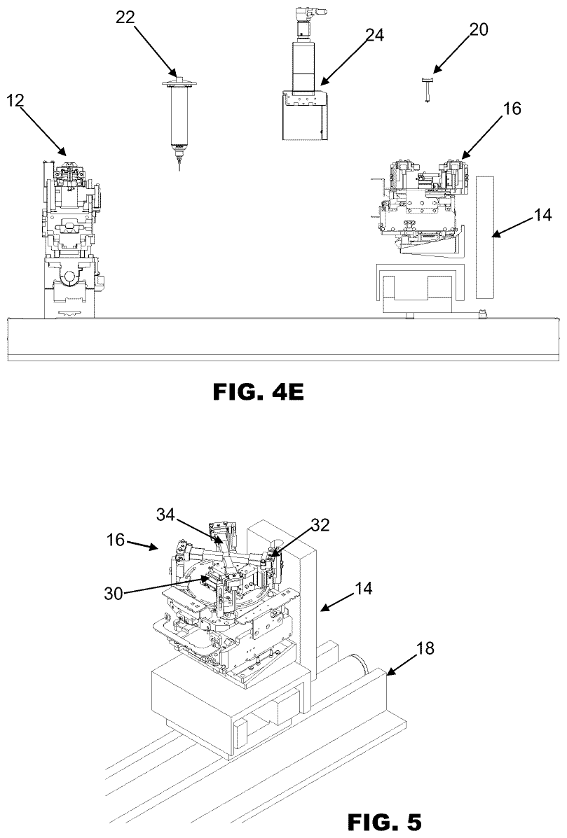

FIGS. 4A to 4E illustrate an exemplary AA process conducted by the AA apparatus 10 according to the preferred embodiment of the invention. In FIG. 4A, an FPC device 100 (or a non-FPC device 101, as the case may be) containing an image sensor 102 has been placed by the pick head 20 onto the SUT 14. The SUT 14 has conveyed the image sensor 102 to the location where the AA head 12 is situated, and where a lens module 108 has been separately received by a gripper of the AA head 12. An AA process is conducted at the AA head 12 to actively align the lens module 108 to the image sensor 102.

In FIG. 4B, the AA process has been completed and the SUT 14 has conveyed the image sensor 102 to a position below the glue dispenser 22. Glue 110 is dispensed onto the periphery of the image sensor 102. Then, the SUT 14 moves the image sensor 102 below the glue inspection module 24 for inspecting the quality of the dispensed glue, as shown in FIG. 4C.

After the glue 110 has been verified to be correctly dispensed, the SUT 14 transports the image sensor 102 back to the AA head 12 as shown in FIG. 4D. At this time, the lens module 108 is placed and attached by the gripper holding it onto the glue 110 that has been dispensed onto the periphery of the image sensor 102 to form an optical package. Before the gripper of the AA head 12 releases the lens module 108 onto the image sensor 102, pre-UV curing is conducted by projecting UV light 114 onto the dispensed glue 110 for a short time (such as one second) to partially cure and slightly harden the glue 110 before the gripper releases the lens module 108. Thereafter, the SUT 14 may start to convey the optical package away from the AA head 12.

FIG. 4E is a side view of a bonded optical package being moved to a position underneath the pick head 20 for offloading. During the time the SUT 14 is conveying the lens module 108 that has been placed onto the image sensor 102 towards the location of the pick head 20, the UV system 16 that is mounted on and movable with the SUT 14 simultaneously activates the UV lamps 112 to project UV light 114 onto the dispensed glue 110 in order to further cure the glue 110. The glue 110 should be fully cured by the time the optical package is picked up by the pick head 20 for offloading. Since the SUT 14 does not require curing to be completed before moving the optical package away from the AA head 12, the UPH can be significantly improved.

FIG. 5 is an isometric view of the SUT 14 comprised in the AA apparatus 10 of FIG. 3. The SUT 14 is installed on the guide rail 18, and is configured to be reciprocally movable in linear directions along the guide rail 18. It includes an SUT tooling 30 which is generally designed to receive and hold an FPC device 100 or a non-FPC device 101 while the SUT 14 moves between the locations of the pick head 20 and the AA head 12. In addition, the UV system 16, which incorporates UV mounts 32, is installed over the SUT tooling 30. The UV mounts 32 are designed for mounting multiple UV lamps 34. In particular, four UV lamps 34 are arranged at equal angular offsets from one another. The UV lamps 34 are capable of projecting UV light 114 onto an optical package comprising a lens module 108 and image sensor 102 that are positioned on the SUT tooling 30 for bonding, both when the SUT 14 is stationary and when it is moving.

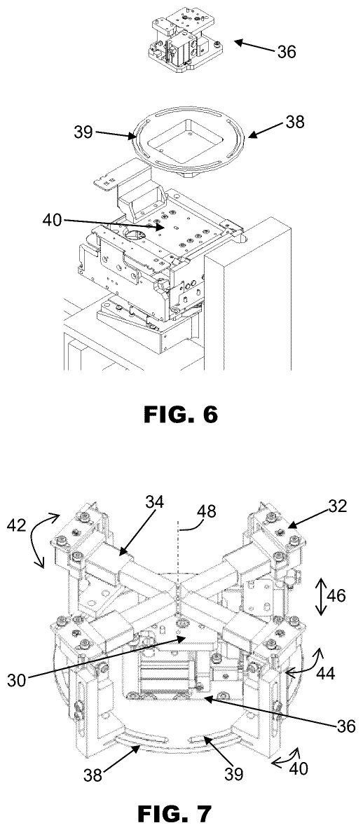

FIG. 6 is an exploded view of the SUT 14 shown in FIG. 5 with its UV system 16 removed. The SUT 14 has an SUT module 40 on which an SUT tooling base 36 of the SUT tooling 30 is installed. The SUT tooling base 36 is surrounded by a UV system mounting base 38 that supports the UV mounts 32 so that the UV lamps 34 are mountable at various distances and angular positions with respect to the SUT tooling base 36. Fastening screws of the SUT tool base 36 may be installed onto the SUT module 40, while the UV system mounting base 38 has pre-drilled through slots 39 through which the UV system 16 is mountable. This mounting design eliminates the need for additional fasteners, saving space and facilitating easy disassembly. With this arrangement, the UV lamps 34 may be installed to generally surround an optical module that is placed on the SUT tooling 30 with UV light 114.

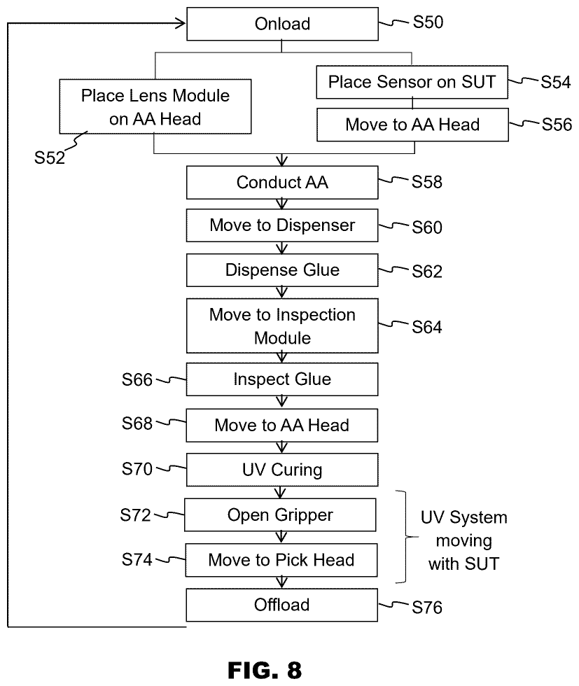

FIG. 7 is an isometric view of the UV system 16 mounted on the SUT 14. There is a total of four arc-shaped through slots 39 which are machined into the UV system mounting base 38, which enable the UV mounts 32 to be locked along these arc-shaped through slots 39. When these lock screws are loosened, the angles of the UV lamps 34 may be adjusted with respect to a central AA axis 48 which correspond to a central alignment axis of the AA head 12 when conducting AA. For instance, the adjustment range of each UV mount 32 may be along respective 30-degree angles. This enables the UV mounts 32 to be adjusted in rotary directions 40 about the said central AA axis 48 for adjustment of the UV lamps 34 held by the UV mounts 32.

Mechanisms are also adopted for adjusting the UV lamps 34 to project the angles of the UV light 114 in various orientations. These include but is not limited to UV pitch adjustment tilting directions 42 about a horizontal axis by loosening lock screws on the UV mounts 32, UV yaw adjustment to rotate the UV lamps 34 in rotary directions 44 about a vertical axis passing through each UV mount 32, UV width adjustment to move the UV lamps 32 towards or away from the central AA axis 48 to fit different package sizes, as well as UV vertical adjustment by raising and lowering the UV lamps 34 in vertical directions 46. These adjustment mechanisms offer flexibility to cater to different types and sizes of optical packages that may be worked upon by the AA apparatus 10.

FIG. 8 is a flowchart showing a typical AA process flow where no glue dispensing failure is encountered. Onloading (S50) is first conducted wherein a lens module is placed onto the AA head using a gripper (S52). Contemporaneously, an image sensor is placed onto the SUT (S54) and the SUT moves the image sensor to the AA head for bonding (S56).

At the AA head, AA is conducted (S58). Then, the SUT moves the image sensor to the location of the glue dispenser (S60), where glue is dispensed onto a periphery of the image sensor (S62). Next, the SUT moves the image sensor to the location of the glue inspection module (S64), where the dispensed glue is inspected for any glue dispensing failure (S66). If there is no glue dispensing failure, the SUT moves the image sensor to the location of the AA head (S68), where the lens module is placed onto the glue that has been dispensed onto the periphery of the image sensor.

At this point, the UV system may start the UV curing process of the optical package (S70) by conducting pre-UV curing at the location of the AA head while the gripper on the AA head is still holding onto the lens module. During this time, UV light may be projected onto the optical package for about one second to slightly harden the glue before the gripper opens and releases its grip on the lens module (S72). Then, the SUT starts transporting the optical package away from the AA head whilst simultaneously continuing UV curing when the SUT is moving towards the pick head. When the SUT is at the location of the pick head, the pick head will move to pick up the optical package from the SUT (S74) and offload the optical package from the AA apparatus (S76).

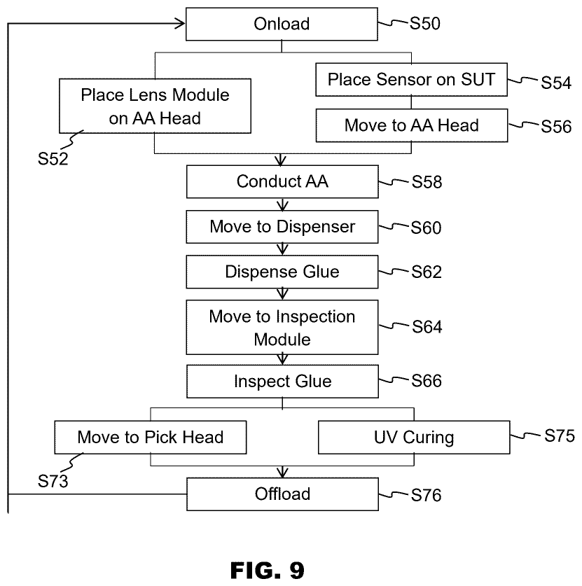

FIG. 9 is a flowchart showing an AA process flow where a glue dispensing failure is encountered. The steps from S50 to S66 above are the same and will not be repeated.

If inspection by the glue inspection module detects that there is a glue dispensing failure the SUT may immediately convey the image sensor to an offloading location at the position of the pick head (S73) in order to offload the image sensor (S76). For instance, there may have been ineffective glue dispensing including but not limited to broken glue, insufficient glue, or excessive glue. Simultaneously, UV curing of the glue that has been dispensed onto the image sensor is conducted (S75) by projecting UV light from the UV system to solidify the glue (without attaching the lens module to the image sensor) before the image sensor is offloaded from the AA apparatus via removal by the pick head (S76) for preventing contamination of the pick head.

It should be appreciated that the preferred embodiment of the UV curing system as described above avoids the need for the optical package assembly operations to be conducted strictly sequentially. The UV system 16 further has a miniaturized adjustment mounting structure that allows the UV curing system to be adjusted when it is being installed on the SUT 14 to cater for different types and sizes of optical packages. As the UV curing system is capable of curing a bond between the lens module 108 and the image sensor 102 at the same time as the SUT 14 is moving, the UV curing process may further be conducted simultaneously as an offloading process or in parallel with a glue dispensing failure rejection process.

Hence, the productivity or UPH of the AA apparatus 10 is increased and the miniaturized multi-degree-of-freedom adjusting structure allows UV lamps 34 to be adjusted independently, making the UV system 16 more flexible and convenient for users.

The invention described herein is susceptible to variations, modifications and/or additions other than those specifically described and it is to be understood that the invention includes all such variations, modifications and/or additions which fall within the spirit and scope of the above description.

1. Method for assembling an optical package including first and second optical components, the method comprising the steps of:
placing the first optical component onto a transporter;
conveying the first optical component with the transporter to a location where an optical alignment head is situated;
aligning the first optical component with respect to the second optical component using the optical alignment head;
dispensing an adhesive onto the first optical component and attaching the second optical component onto the adhesive dispensed on the first optical component to form the optical package; and thereafter
conveying the optical package away from the optical alignment head using the transporter while simultaneously curing the adhesive with ultraviolet light projected from an ultraviolet system mounted on and movable with the transporter.

2. The method as claimed in claim 1, wherein the step of attaching the second optical component onto the adhesive comprises placing the second optical component onto the adhesive with a gripper, and the method further comprises the step of partially curing the adhesive by projecting ultraviolet light onto the dispensed adhesive after forming the optical package but before the gripper releases the second optical component for the transporter to convey the optical package away from the optical alignment head.

3. The method as claimed in claim 2, wherein while the transporter is moving the optical package towards a pick head for offloading, ultraviolet light is further projected onto the dispensed adhesive in order to fully cure the adhesive.

4. The method as claimed in claim 1, wherein the ultraviolet system incorporates ultraviolet mounts installed on the transporter for mounting multiple ultraviolet lamps for projecting the ultraviolet light onto the optical package which is positioned on a tooling base of the transporter.

5. The method as claimed in claim 4, wherein the multiple ultraviolet lamps are arranged at equal angular offsets from one another to surround the optical package.

6. The method as claimed in claim 4, wherein the ultraviolet system includes an ultraviolet system mounting base which surrounds the tooling base of the transporter, and the ultraviolet mounts are supported by the ultraviolet system mounting base.

7. The method as claimed in claim 6, wherein the ultraviolet system mounting base includes arc-shaped through slots for adjusting the ultraviolet mounts in rotary directions with respect to a central axis corresponding to a central alignment axis of the optical alignment head.

8. The method as claimed in claim 7, wherein each ultraviolet mount includes mechanisms for rotating the ultraviolet lamps in pitch adjustment tilting directions about a horizontal axis and yaw adjustment to rotate the ultraviolet lamps in rotary directions about a vertical axis passing through each ultraviolet mount.

9. The method as claimed in claim 7, wherein the ultraviolet mount includes mechanisms for width adjustment for moving the ultraviolet mounts towards and away from the central axis, and vertical adjustment for raising and lowering the ultraviolet mounts.

10. The method as claimed in claim 1, wherein dispensing of the adhesive is conducted at an adhesive dispenser, and the method further comprises the step of inspecting the dispensed adhesive at an adhesive inspection module separate from the adhesive dispenser.

11. The method as claimed in claim 10, wherein the transporter conveys the first optical component from a location of the adhesive inspection module back to the location of the optical alignment head for attaching the second optical component if the adhesive is verified by the adhesive inspection module to be correctly dispensed.

12. The method as claimed in claim 1, wherein the first optical component comprises an image sensor and the second optical component comprises a lens module.

13. Method for assembling an optical package including first and second optical components, the method comprising the steps of:
placing the first optical component onto a transporter;
conveying the first optical component with the transporter to a location where an optical alignment head is situated;
aligning the first optical component with respect to the second optical component using the optical alignment head;
dispensing an adhesive onto the first optical component and inspecting the dispensed adhesive at an adhesive inspection module;
if adhesive dispensing failure is detected by the adhesive inspection module, conveying the first optical component towards an offloading location while simultaneously curing the adhesive with ultraviolet light projected from an ultraviolet system mounted on and moveable with the transporter; and
removing the first optical component from the transporter after curing the adhesive.

14. An apparatus for assembling an optical package including first and second optical components, the apparatus comprising:
an optical alignment head for aligning the first optical component with respect to the second optical component;
a transporter for conveying the first optical component to a location where the optical alignment head is situated;
an adhesive dispenser for dispensing an adhesive onto the first optical component before attaching the second optical component onto the adhesive dispensed on the first optical component at the optical alignment head to form the optical package; and
an ultraviolet system mounted on and movable with the transporter such that ultraviolet light is projectable onto the optical package to cure the adhesive simultaneously with conveying the optical package away from the optical alignment head with the transporter.
